(19) United States
(12) Patent Application Publication
(10) Pub. No.: US 2024/0237348 A1
(43) Pub. Date: Jul. 11, 2024

(54) SEMICONDUCTOR MEMORY DEVICE AND METHOD OF MANUFACTURING THE SAME

(71) Applicant: SAMSUNG ELECTRONICS CO., LTD., Suwon-si (KR)

(72) Inventors: Hwayeong LEE, Suwon-si (KR); Hunmo Yang, Suwon-si (KR); Seulji Song, Suwon-si (KR)

(21) Appl. No.: 18/403,115

(22) Filed: Jan. 3, 2024

(30) Foreign Application Priority Data
Jan. 5, 2023 (KR) 10-1023-0001950

(51) Int. Cl. H10B 43/27; G11C 5/06; G11C 16/04; H10B 41/10; H10B 41/27; H10B 43/10

(52) U.S. Cl. CPC H10B 43/27; G11C 5/063; G11C 16/0483; H10B 41/10; H10B 41/27; H10B 43/10

(57) ABSTRACT

A semiconductor memory device includes a semiconductor substrate; a plurality of word line layers on the semiconductor substrate, each word line layer of the plurality of word line layers including an insulating line and a word line; a plurality of insulating layers in spaces between the plurality of word line layers, the plurality of insulating layers being apart from each other in a vertical direction on the semiconductor substrate; a channel structure extending in the vertical direction on the semiconductor substrate, the channel structure including a channel region and a gate dielectric layer surrounding the channel region; and a bit line on the channel structure, the bit line extending in a first horizontal direction perpendicular to the vertical direction and being connected to the channel structure, wherein the word line of each word line layer of the plurality of word line layers has a meandering shape.

### CROSS-REFERENCE TO RELATED APPLICATION

This application is based on and claims priority under 35 U.S.C. § 119 to Korean Patent Application No. 10-2023-0001950, filed on Jan. 5, 2023, in the Korean Intellectual Property Office, the disclosure of which is incorporated by reference herein in its entirety.

### BACKGROUND

### 1. Field

Embodiments relate to a semiconductor memory device and a manufacturing method thereof.

### 2. Description of the Related Art

As electronic products have been miniaturized and multifunctional and have high-performance, an increased degree of integration may provide high-capacity semiconductor memory devices.

### SUMMARY

The embodiments may be realized by providing a semiconductor memory device including a semiconductor substrate; a plurality of word line layers on the semiconductor substrate, each word line layer of the plurality of word line layers including an insulating line and a word line; a plurality of insulating layers in spaces between the plurality of word line layers, the plurality of insulating layers being apart from each other in a vertical direction on the semiconductor substrate; a channel structure extending in the vertical direction on the semiconductor substrate, the channel structure including a channel region and a gate dielectric layer surrounding the channel region; and a bit line on the channel structure, the bit line extending in a first horizontal direction perpendicular to the vertical direction and being connected to the channel structure, wherein the word line of each word line layer of the plurality of word line layers has a meandering shape.

The embodiments may be realized by providing a semiconductor memory device including a semiconductor substrate; a plurality of word line layers on the semiconductor substrate, each word line layer of the plurality of word line layers including an insulating line and a word line; a plurality of insulating layers in spaces between the plurality of word line layers, the plurality of insulating layers being spaced apart from each other in a vertical direction on the semiconductor substrate; a channel structure having a cylindrical shape and extending in the vertical direction on the semiconductor substrate, the channel structure including a channel region and a gate dielectric layer surrounding the channel region; and a bit line on the channel structure, the bit line extending in a first horizontal direction perpendicular to the vertical direction and being connected to the channel structure, wherein the word line of each word line layer of the plurality of word line layers has a meandering shape, and thicknesses of the plurality of word line layers in the vertical direction increase with increasing distance away from the semiconductor substrate in the vertical direction.

The embodiments may be realized by providing a semiconductor memory device including a semiconductor substrate; a plurality of word line layers on the semiconductor substrate, each word line layer of the plurality of word line layers including an insulating line and a word line; a plurality of insulating layers in spaces between the plurality of word line layers, the plurality of insulating layers being spaced apart from each other in a vertical direction on the semiconductor substrate; a channel structure having a cylindrical shape and extending in the vertical direction on the semiconductor substrate, the channel structure including a channel region and a gate dielectric layer surrounding the channel region; and a bit line on the channel structure, the bit line extending in a first horizontal direction perpendicular to the vertical direction and being connected to the channel structure, wherein the word line of each word line layer of the plurality of word line layers has a meandering shape, thicknesses of the plurality of word line layers in the vertical direction increase with increasing distance away from the semiconductor substrate in the vertical direction, the plurality of word line layers include a first word line layer having a first thickness in the vertical direction; a second word line layer having a second thickness in the vertical direction, the second word line layer being spaced apart from the first word line layer in the vertical direction and being on the first word line layer; and a third word line layer having a third thickness in the vertical direction, the third word line layer being spaced apart from the second word line layer in the vertical direction and being on the second word line layer, the first word line layer, the second word line layer, and the third word line layer are sequentially stacked on the semiconductor substrate, the first thickness of the first word line layer is less than the second thickness of the second word line layer, and the second thickness of the second word line layer is less than the third thickness of the third word line layer.

### BRIEF DESCRIPTION OF THE DRAWINGS

Features will be apparent to those of skill in the art by describing in detail exemplary embodiments with reference to the attached drawings in which:

FIG. 1 is a block diagram of a semiconductor memory device according to embodiments;

FIG. 2 is a schematic perspective view of a semiconductor memory device according to embodiments;

FIG. 3 is an equivalent circuit diagram of a memory cell array of a semiconductor memory device according to embodiments;

FIGS. 4A and 4B are perspective views illustrating a semiconductor memory device according to an embodiment;

FIG. 5 is a cross-sectional view of a semiconductor memory device according to an embodiment taken in word line layers;

FIG. 6 is a vertical cross-sectional view of a semiconductor memory device according to an embodiment; and

FIGS. 7 to 11 are perspective views of stages in a method of manufacturing a semiconductor memory device, according to embodiments.

### DETAILED DESCRIPTION

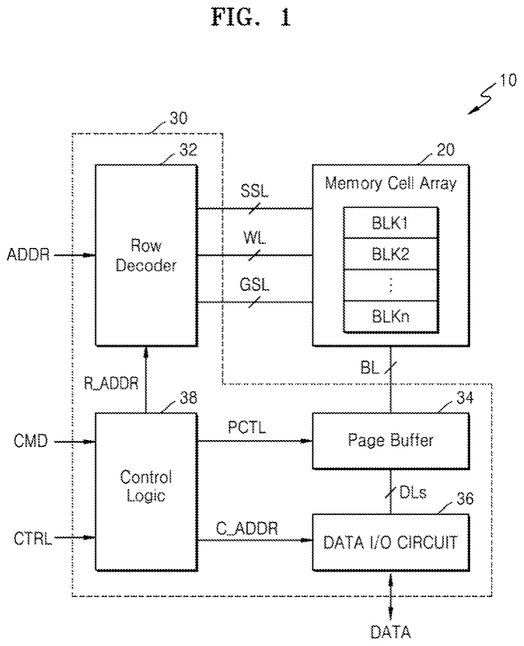

FIG. 1 is a block diagram of a nonvolatile memory device 10 according to embodiments.

Referring to FIG. 1, the nonvolatile memory device 10 may include a memory cell array 20 and a peripheral circuit 30. The memory cell array 20 includes a plurality of memory cell blocks BLK1, BLK2, . . . , BLKn. Each of the memory cell blocks BLK1, BLK2, . . . , BLKn may include a plurality of memory cells. The memory cell blocks BLK1, BLK2, . . . , BLKn may be connected to the peripheral circuit 30 through a bit line BL, a word line WL, a string select line SSL, and a ground select line GSL.

The peripheral circuit 30 may include a row decoder 32, a page buffer 34, a data input/output (I/O) circuit 36, and a control logic 38. In an implementation, the peripheral circuit 30 may further include an I/O interface, a column logic, a voltage generator, a pre-decoder, a temperature sensor, a command decoder, an address decoder, an amplifier circuit, or the like.

The memory cell array 20 may be connected to the page buffer 34 through a bit line BL and may be connected to the row decoder 32 through a word line WL, a string select line SSL, and a ground select line GSL. In the memory cell array 20, each of the memory cells included in the memory cell blocks BLK1, BLK2, . . . , BLKn may be a flash memory cell. The memory cell array 20 may include a 3D memory cell array. The 3D memory cell array may include a plurality of NAND strings, and each NAND string may include a plurality of memory cells respectively connected to a plurality of word lines WL vertically stacked on a substrate.

The peripheral circuit 30 may receive an address ADDR, a command CMD, and a control signal CTRL from the outside of the nonvolatile memory device 10, and may transmit and receive data DATA to and from a device outside the nonvolatile memory device 10.

In response to the address ADDR from the outside, the row decoder 32 may select at least one of the memory cell blocks BLK1, BLK2, . . . , BLKn, and may select the word line WL, the string select line SSL, and the ground select line GSL of the selected memory cell block. The row decoder 32 may transfer a voltage for performing a memory operation to the word line WL of the selected memory cell block.

The page buffer 34 may be connected to the memory cell array 20 through the bit line BL. During a program operation, the page buffer 34 may operate as a write driver to apply a voltage according to the data DATA to be stored in the memory cell array 20 to the bit line BL, and during a read operation, the page buffer 34 may operate as a sense amplifier to sense the data DATA stored in the memory cell array 20. The page buffer 34 may operate according to a control signal PCTL provided from the control logic 38.

The data I/O circuit 36 may be connected to the page buffer 34 through data lines DLs. During a program operation, the data I/O circuit 36 may receive data DATA from a memory controller and provide program data DATA to the page buffer 34 based on a column address C_ADDR provided from the control logic 38. During a read operation, the data I/O circuit 36 may provide the read data DATA stored in the page buffer 34 to the memory controller based on the column address C_ADDR provided from the control logic 38.

The data I/O circuit 36 may transfer an input address or command to the control logic 38 or the row decoder 32. The peripheral circuit 30 may further include an electro static discharge (ESD) circuit and a pull-up/pull-down driver.

The control logic 38 may receive a command CMD and a control signal CTRL from the memory controller. The control logic 38 may provide the row address R_ADDR to the row decoder 32 and the column address C_ADDR to the data I/O circuit 36. The control logic 38 may generate various internal control signals used in the nonvolatile memory device 10 in response to the control signal CTRL. In an implementation, the control logic 38 may adjust voltage levels provided to the word line WL and the bit line BL when a memory operation, such as a program operation or an erase operation, is performed.

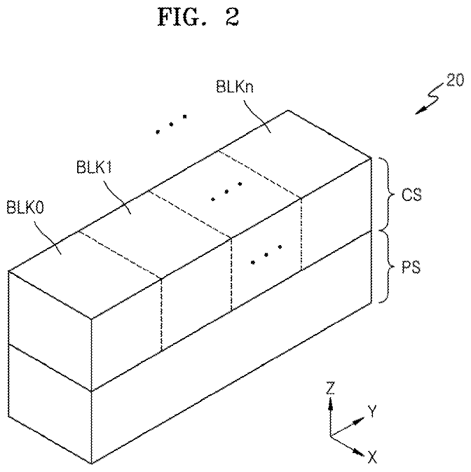

FIG. 2 is a schematic perspective view of a memory cell array 20 according to embodiments.

Referring to FIG. 2, the memory cell array 20 may include a cell array structure CS and a peripheral circuit structure PS overlapping each other in a vertical direction (a Z direction). The cell array structure CS may include the memory cell array 20 described above with reference to FIG. 1. The peripheral circuit structure PS may include the peripheral circuit 30 described with reference to FIG. 1.

The cell array structure CS may include the memory cell blocks BLK1, BLK2, . . . , BLKn. Each of the memory cell blocks BLK1, BLK2, . . . , BLKn may include three-dimensionally arranged memory cells.

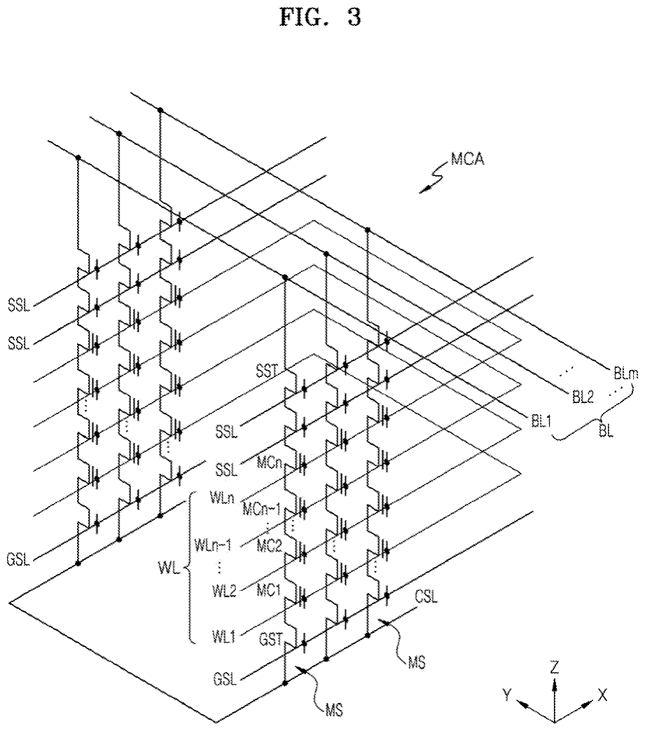

FIG. 3 is an equivalent circuit diagram of a memory cell array MCA of a nonvolatile memory device according to embodiments.

Referring to FIG. 3, the memory cell array MCA may include a plurality of memory cell strings MS. The memory cell array MCA may include a plurality of bit lines BL (BL1, BL2, . . . , BLm), a plurality of word lines WL (WL1, WL2, . . . , WLn-1, WLn), at least one string select line SSL, at least one ground select line GSL, and a common source line CSL. The memory cell strings MS may be formed between the bit lines BL (BL1, BL2, . . . , BLm) and the common source line CSL. In an implementation, as illustrated in FIG. 3, each of the memory cell strings MS may include two string select lines SSL. In an implementation, each of the memory cell strings MS may include a different number of string select lines SSL.

Each of the memory cell strings MS may include two string select transistors SST, a ground select transistor GST, and a plurality of memory cell transistors MC1, MC2, . . . , MCn-1, MCn. A drain region of the string select transistor SST may be connected to a corresponding one of the bit lines BL (BL1, BL2, . . . , BLm), and a source region of the ground select transistor GST may be connected to the common source line CSL. The common source line CSL may be a region to which source regions of a plurality of ground select transistors GST are connected in common.

The string select transistor SST may be connected to the string select line SSL, and the ground select transistor GST may be connected to the ground select line GSL. The memory cell transistors MC1, MC2, . . . , MCn-1, MCn may be connected to the word lines WL (WL1, WL2, . . . , WLn-1, WLn), respectively.

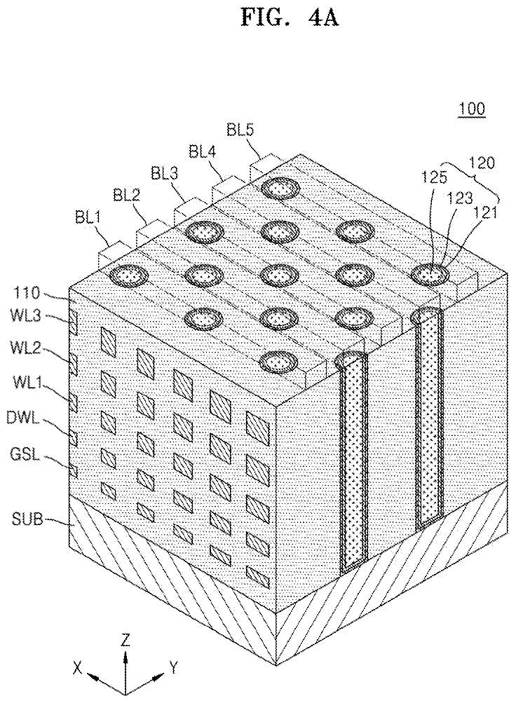

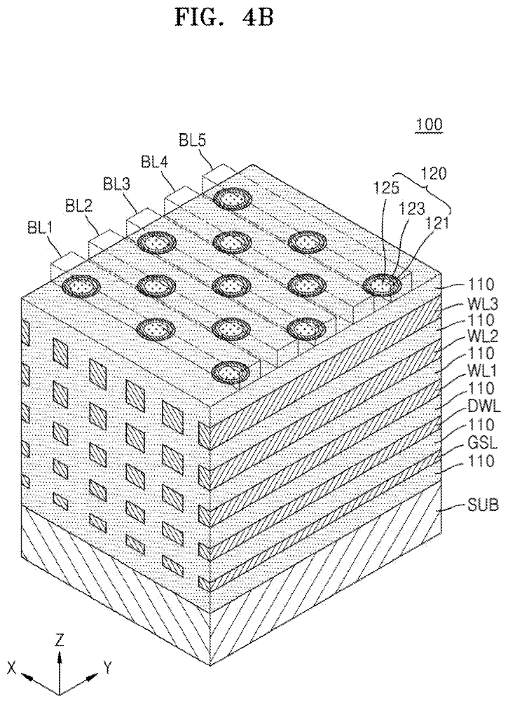

FIGS. 4A and 4B are perspective views illustrating a semiconductor memory device 100 according to an embodiment. In detail, FIG. 4A is a perspective view illustrating a shape of a channel structure taken in a vertical direction. FIG. 4B is a perspective view illustrating a shape of the semiconductor memory device 100 of FIG. 4A partially cut in the vertical direction. In addition, FIGS. 4A and 4B show the semiconductor memory device 100 in a cell region.

Referring to FIGS. 4A and 4B, the semiconductor memory device 100 may include a cell array structure including a cell region. The cell region may be a region in which volatile memory cells having a vertical structure are arranged to form an array. An extension region may be a region in which a connection portion for electrically connecting a memory cell array formed in the cell region to a peripheral circuit region is formed in a stepped shape.

A semiconductor substrate SUB may include, e.g., silicon (Si). In an implementation, the semiconductor substrate SUB may include a semiconductor element, e.g., germanium (Ge), or a compound semiconductor, e.g., silicon carbide (SiC), gallium arsenide (GaAs), indium arsenide (InAs), or indium phosphide (InP). In an implementation, the semiconductor substrate SUB may have a silicon on insulator (SOI) structure. In an implementation, the semiconductor substrate SUB may include a buried oxide (BOX) layer. As used herein, the term “or” is not an exclusive term, e.g., “A or B” would include A, B, or A and B.

In an implementation, a plurality of insulating layers 110 may be spaced at regular intervals from each other in the vertical direction (the Z direction) on the semiconductor substrate SUB. In an implementation, a single insulating layer 110 may continuously surround elements of the memory device. The insulating layers 110 may include, e.g., silicon oxide, silicon nitride, or silicon oxynitride. Each of the insulating layers 110 may be, e.g., a single layer including one kind of insulating film, a double layer including two kinds of insulating films, or a multilayer including a combination of at least three kinds of insulating films.

A ground select line layer GSL, a dummy word line layer DWL, and a plurality of word line layers WL1, WL2, and WL3 may each be on the insulating layer 110 in the vertical direction (the Z direction) and spaced at regular intervals from each other. The ground select line layer GSL, the dummy word line layer DWL, and the word line layers WL1, WL2, and WL3 may include, e.g., doped semiconductor materials (doped silicon, doped germanium, or the like), conductive metal nitride (titanium nitride, tantalum nitride, or the like), metals (tungsten, titanium, tantalum, or the like), or metal-semiconductor compounds (tungsten silicide, cobalt silicide, titanium silicide, or the like).

The ground select line layer GSL may include a ground select line, and the dummy word line layer DWL may include a dummy word line. In an implementation, each of the word line layers WL1, WL2, and WL3 may include a word line and an insulating line. A detailed description of the ground select line layer GSL, the dummy word line layer DWL, and the word line layers WL1, WL2, and WL3 is given below. The insulating line may include the same material as that of the insulating layer 110.

A plurality of channel structures 120 may be spaced apart from each other in a first horizontal direction (an X direction) and a second horizontal direction (a Y direction) on the semiconductor substrate SUB, and may extend (e.g., lengthwise) in the vertical direction (the Z direction). The channel structures 120 may be within vertical openings penetrating the insulating layers 110, the ground select line layer GSL, the dummy word line layer DWL, and the word line layers WL1, WL2, and WL3. In an implementation, the channel structures 120 may have a cylindrical shape. In an implementation, a width of each of the channel structures 120 in the horizontal direction (the X and Y directions) may have a tapered shape decreasing toward the semiconductor substrate SUB.

In an implementation, a plurality of bit lines BL1, BL2, BL3, BL4, and BL5 may be on the channel structures 120. A plurality of bit line contact pads may be between the channel structures 120 and the bit lines BL1, BL2, BL3, BL4, and BL5. The channel structures 120 may be respectively connected to the bit lines BL1, BL2, BL3, BL4, and BL5 through the bit line contact pads. The bit lines BL1, BL2, BL3, BL4, and BL5 may extend in the first horizontal direction (the X direction). Each of the bit lines BL1, BL2, BL3, BL4, and BL5 may include, e.g., metal, metal nitride, or combinations thereof. In an implementation, each of the bit lines BL1, BL2, BL3, BL4, and BL5 may include tungsten, titanium, tantalum, copper, aluminum, titanium nitride, tantalum nitride, tungsten nitride, or combinations thereof.

The channel structures 120 may include a gate dielectric layer 121, a channel region 123, a filling insulating layer 125, and a drain region. The gate dielectric layer 121 may be on an inner wall of the vertical opening. The channel region 123 may be on an inner wall of the gate dielectric layer 121. The filling insulating layer 125 may fill the inside of the vertical opening.

The channel region 123 may include doped polysilicon or undoped polysilicon. The channel region 123 may have a cylindrical shape. An internal space of the channel region 123 may be filled with the filling insulating layer 125. The channel region 123 may include a portion in contact (e.g., direct contact) with the common source line CSL. The filling insulating layer 125 may include an insulating material. In an implementation, the filling insulating layer 125 may include silicon oxide, silicon nitride, SiON, or combinations thereof.

In an implementation, the filling insulating layer 125 may be omitted, and in this case, the channel region 123 may have a pillar structure without an internal space. The drain region may include impurity-doped polysilicon, metal, conductive metal nitride, or combinations thereof. Examples of metals that may constitute the drain region may include tungsten, nickel, cobalt, and tantalum.

In an implementation, as illustrated in FIGS. 4A and 4B, the channel structure 120 may include the gate dielectric layer 121, and the gate dielectric layer 121 may extend in the vertical direction (the Z direction) along the channel region 123.

The ground select line layer GSL, the dummy word line layer DWL, and the word line layers WL1, WL2, and WL3 may be around one channel structure 120. The ground select line layer GSL, the dummy word line layer DWL, and the word line layers WL1, WL2, and WL3 may be adjacent to one end of one channel structure 120 and extend in the first horizontal direction (the X direction) and the second horizontal direction (the Y direction), and may be spaced apart from each other in the vertical direction (the Z direction). The insulating layers 110 may be between the ground select line layer GSL, the dummy word line layer DWL, and the word line layers WL1, WL2, and WL3 neighboring in the vertical direction (the Z direction), respectively. Each of the ground select line layer GSL, the dummy word line layer DWL, and the word line layers WL1, WL2, and WL3 may include, e.g., a doped semiconductor material, a conductive metal nitride, a metal, or a metal-semiconductor compound.

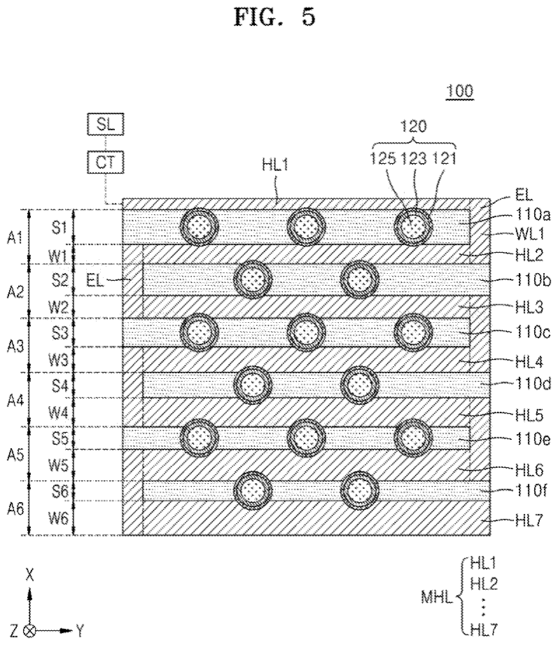

FIG. 5 is a cross-sectional view of a semiconductor memory device according to an embodiment taken in word line layers. Descriptions are given together with FIGS. 4A and 4B, and descriptions already given above with reference to FIGS. 4A and 4B may be briefly given or omitted.

Referring to FIG. 5, each of the ground select line layer GSL, the dummy word line layer DWL, and the word line layers WL1, WL2, and WL3 may include a word line and an insulating line. The word line and the insulating line may have the same thickness as that of the word line layers WL1, WL2, and WL3 in the vertical direction (the Z direction). Each of the word line layers WL1, WL2, and WL3 may include the word line extending in the first horizontal direction (the X direction) and the second horizontal direction (the Y direction). The word line may have a meandering shape on an X-Y plane within the word line layers WL1, WL2, and WL3.

The word line may include a plurality of edge lines EL and a plurality of horizontal lines MHL. Each of the edge lines EL may be connected to at least two horizontal lines among the horizontal lines MHL. The edge lines EL may extend in the first horizontal direction (the X direction). Each of the edge lines EL may have the same width in the second horizontal direction (the Y direction) and may extend in the first horizontal direction (the X direction). Each of the edge lines EL may not vertically overlap the bit lines (BL2, BL3, BL4, and BL5, referring to FIGS. 4A and 4B). Each of the edge lines EL may be adjacent to a sidewall of the word line layer.

In an implementation, the horizontal lines MHL may extend in the second horizontal direction (the Y direction). The horizontal lines MHL may be spaced apart from each other in the first horizontal direction (the X direction). The horizontal lines MHL may have different widths.

In an implementation, the horizontal lines MHL may include, e.g., a first horizontal line HL1, a second horizontal line HL2, a third horizontal line HL3, a fourth horizontal line HL4, a fifth horizontal line HL5, a sixth horizontal line HL6, and a seventh horizontal line HL7. In an implementation, a width of the first horizontal line HL1 in the first horizontal direction may be less than a width W1 of the second horizontal line HL2 in the first horizontal direction. Hereinbelow, the width of the first horizontal line HL1 in the first horizontal direction is referred to as W0. The width W1 of the second horizontal line HL2 in the first horizontal direction may be less than a width W2 of the third horizontal line HL3 in the first horizontal direction. In an implementation, the widths W0, W1, W2, W3, W4, W5, and W6 of the first to seventh horizontal lines HL1, HL2, HL3, HL4, HL5, HL6, and HL7 may increase from the first horizontal line HL1 to the seventh horizontal line HL7 (e.g., the width of each higher numbered horizontal line may be greater than the width of each lower numbered horizontal line).

Insulating lines 110a, 110b, 110c, 110d, 110e, and 110f may be spaced apart from each other and may be in spaces between the first to seventh horizontal lines HL1, HL2, HL3, HL4, HL5, HL6, and HL7. The insulating lines 110a, 110b, 110c, 110d, 110e, and 110f may include, e.g., a first insulating line 110a, a second insulating line 110b, a third insulating line 110c, a fourth insulating line 110d, and a fifth insulating line 110e, and a sixth insulating line 110f. In an implementation, the first insulating line 110a may be connected to the edge line EL on one side and connected to a contact CT on the other side. The contact CT may include a metal contact. The contact CT may be electrically connected to a source line SL and may supply a voltage applied from the source line SL to the word line.

The first to sixth insulating lines 110a, 110b, 110c, 110d, 110e, and 110f may have different widths. The first to sixth insulating lines 110a, 110b, 110c, 110d, 110e, and 110f may be parallel to each other on the plane of the word line layer and may be arranged in zigzags in the second horizontal direction (the Y direction).

In an implementation, the first insulating line 110a may contact the edge line EL, the first horizontal line HL1, and the second horizontal line HL2. The second insulating line 110b may contact the edge line EL, the second horizontal line HL2, and the third horizontal line HL3. In an implementation, a width S1 of the first insulating line 110a in the first horizontal direction may be greater than a width S2 of the second insulating line 110b in the first horizontal direction. The width S2 of the second insulating line 110b in the first horizontal direction may be greater than a width S3 of the third insulating line 110c in the first horizontal direction. In an implementation, the widths S1, S2, S3, S4, S5, and S6 of the plurality of insulating lines 110a, 110b, 110c, 110d, 110e, and 110f may decrease from the first insulating line 110a to the sixth insulating line 110f.

In an implementation, a sum A1 of the width S1 of the first insulating line 110ain the first horizontal direction and the width W1 of the second horizontal line HL2 in the first horizontal direction may be equal to a sum A2 of the width S2 of the second insulating line 110b and width W3 of the third horizontal line HL3 in the first horizontal direction. In an implementation, a sum A3 of the width S3 of the third insulating line 110c in the first horizontal direction and the width W3 of the fourth horizontal line HL4 in the first horizontal direction may be equal to a sum A4 of the width S4 of the fourth insulating line 110d in the first horizontal direction and the width W4 of the fifth horizontal line HL5 in the first horizontal direction. In an implementation, a width ratio of any one of the first to seventh horizontal lines HL1, HL2, HL3, HL4, HL5, HL6, and HL7 and any one of the first to sixth insulating lines 110a, 110b, 110c, 110d, 110e, and 110f may be about 1:1 to about 10:1. In this case, a set of horizontal line and insulating line may refer to a horizontal line and an insulating line that are in contact with each other.

In an implementation, in the word line layer, the first to seventh horizontal lines HL1, HL2, HL3, HL4, HL5, HL6, and HL7 and the first to sixth insulating lines 110a, 110b, 110c, 110d, 110e, and 110f may vary in width in the first horizontal direction (the X direction), and the sum of one horizontal line and one insulating line may be maintained to be constant (e.g., A1, A2, A3, A4, A5, and A6). In an implementation, each of the first to seventh horizontal lines HL1, HL2, HL3, HL4, HL5, HL6, and HL7 of the word line layer may increase in width in the first horizontal direction with increasing distance away from the contact CT. In an implementation, each of the first to sixth insulating lines 110a, 110b, 110c, 110d, 110e, and 110f of the word line layer may decrease in width in the first horizontal direction with increasing distance away from the contact CT. In an implementation, the meandering shape of the word lines in the word line layer may be a zig-zag arrangement, e.g., in which the first to seventh horizontal lines HL1, HL2, HL3, HL4, HL5, HL6, and HL7 extend in parallel in the Y direction, and a first edge line EL connects adjacent ends of the first and second horizontal lines HL1 and HL2, a second edge line EL connects adjacent ends of the second and third horizontal lines HL2 and HL3 that are opposite to the adjacent ends of the first and second horizontal lines HL1 and HL2 connected by the first edge line EL, etc., such that the word lines have the meandering shape as illustrated in FIG. 5.

In an implementation, by forming the horizontal line (e.g., the first horizontal line HL1) on one side, to which a voltage is supplied, to have a width different from those of the other horizontal lines, resistance in the word line layer may decrease and a voltage drop phenomenon may be prevented. In an implementation, by forming the word line layer having the meandering word lines, leakage current that may occur in the semiconductor memory device 10 may be prevented.

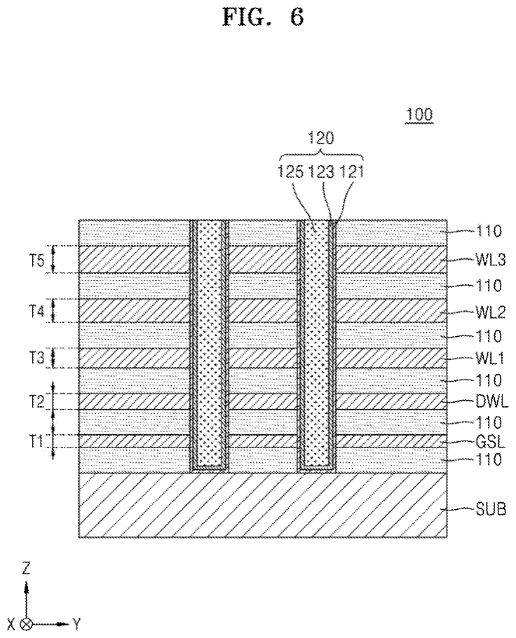

FIG. 6 is a vertical cross-sectional view of the semiconductor memory device 100 according to an embodiment. Descriptions are given together with FIGS. 4A and 4B, and descriptions already given above with reference to FIGS. 4A and 4B may be briefly given or omitted. In FIG. 6, the channel structure is shown for ease of understanding.

Referring to FIG. 6, the ground select line layer GSL, the dummy word line layer DWL, and the word line layers WL1, WL2, and WL3 may have different thicknesses in the vertical direction (the Z direction). The word line layers WL1, WL2, and WL3 may include a first word line layer WL1, a second word line layer WL2, and a third word line layer WL3. The dummy word line layer DWL may be the same word line layer as the word line layers WL1, WL2, and WL3. In addition, each of the ground select line layer GSL, the dummy word line layer DWL, and the word line layers WL1, WL2, and WL3 may be a gate electrode of a memory cell transistor.

Each of the ground select line layer GSL, the dummy word line layer DWL, and the word line layers WL1, WL2, and WL3 may be sequentially stacked to be apart from another with the insulating layer 110 therebetween on the substrate SUB. In an implementation, each of the ground select line layer GSL, the dummy word line layer DWL, and the word line layers WL1, WL2, and WL3 may increase in thickness with increasing distance away from the substrate SUB (in the Z direction). In an implementation, a thickness T2 of the dummy word line layer DWL may be greater than a thickness T1 of the ground select line layer GSL. In an implementation, a thickness T4 of the second word line layer WL2 may be greater than a thickness T3 of the first word line layer WL1. In an implementation, a thickness T5 of the third word line layer WL3 may be greater than the thickness T4 of the second word line layer WL2.

In an implementation, a ratio of the thinnest word line layer among the word line layers WL1, WL2, and WL3 and the thickest word line layer among the word line layers WL1, WL2, and WL3 may be about 1:2. to about 1:10. In an implementation, by differentially adjusting the thickness of each of the ground select line layer GSL, the dummy word line layer DWL, and the word line layers WL1, WL2, and WL3, a difference in wiring resistance between a memory cell located in a lower layer and a memory cell located in an upper layer may be reduced.

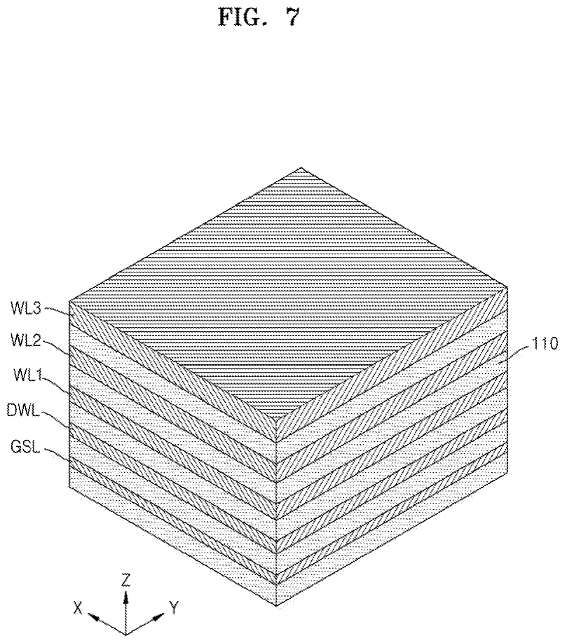

FIGS. 7 to 11 are perspective views of stages in a method of manufacturing the semiconductor memory device 100, according to embodiments.

For convenience of description, a region from the insulating layer 110 to the third word line layer WL3 on the substrate SUB of the semiconductor memory device 100 is mainly described.

Referring to FIG. 7, the ground select line layer GSL, the dummy word line layer DWL, the word line layers WL1, WL2, and WL3, and the insulating layer 110 may be alternately stacked on a semiconductor substrate.

First, the insulating layer 110 and the ground selection line layer GSL may be sequentially formed on the semiconductor substrate SUB. Next, the insulating layer 110 and the dummy word line layer DWL may be formed on the ground select line layer GSL. Thereafter, the first word line layer WL1, the second word line layer WL2, and the third word line layer WL3 may be formed on the dummy word line layer DWL. Forming such a stacked structure may be sequentially and repeatedly performed. In an implementation, the thickness of the insulating layer 110 may be uniform, and the ground select line layer GSL, the dummy word line layer DWL, and the word line layers WL1, WL2, and WL3 may have different thicknesses. In an implementation, the ground select line layer, the dummy word line layer DWL, and the word line layers WL1, WL2, and WL3 may be sequentially stacked to increase in thickness in this stated order.

In an implementation, the insulating layers 110, the ground select line layer GSL, the dummy word line layer DWL, and the word line layers WL1, WL2, and WL3 may be formed by chemical vapor deposition (CVD), plasma-enhanced CVD (PECVD), or atomic layer deposition (ALD).

In an implementation, the insulating layers 110, the ground select line layer GSL, the dummy word line layer DWL, and the word line layers WL1, WL2, and WL3 may include materials having etch selectivity with respect to each other. In an implementation, the insulating layers 110 may be formed using silicon oxide, and each of the ground select line layer GSL, the dummy word line layer DWL, and the word line layers WL1, WL2, and WL3 may be formed using other silicon materials. In an implementation, each of the insulating layers 110, the ground select line layer GSL, the dummy word line layer DWL, and the word line layers WL1, WL2, and WL3 may have a thickness of about several tens of nanometers (nm).

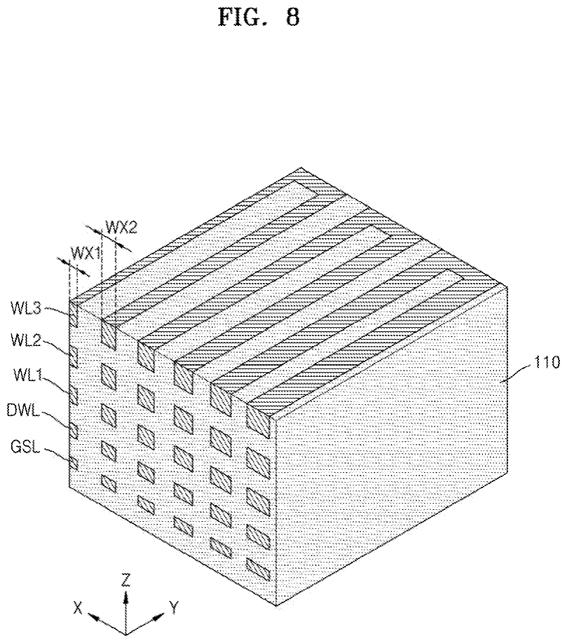

Referring to FIG. 8, a first mask pattern may be formed on the third word line layer WL3, portions of the insulating layers 110, the ground select line layer GSL, the dummy word line layer DWL, and the word line layers WL1, WL2, and WL3 may be removed using the first mask pattern as an etch mask, and the insulating layer 110 may be further formed in a space between etched portions.

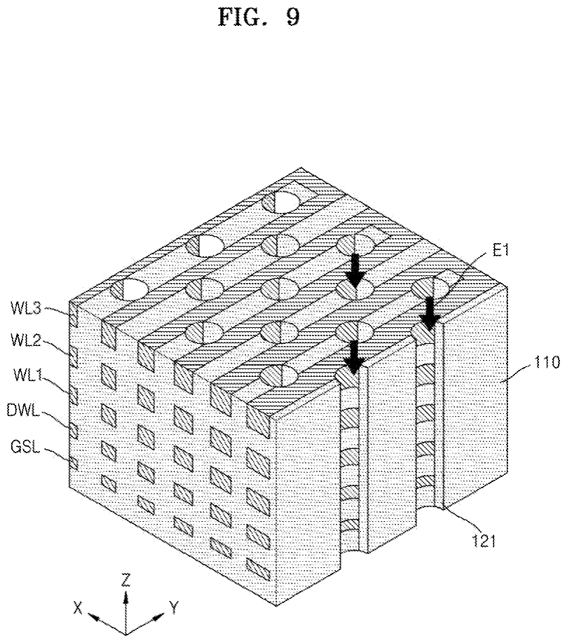

Referring to FIG. 9, a second mask pattern may be formed on the third word line layer WL3, and portions of the insulating layers 110, the ground select line layer GSL, the dummy word line layer DWL, and the word line layers WL1, WL2, and WL3 may be etched E1 to form an opening.

The opening may expose an upper surface of the semiconductor substrate. The opening may be provided in plurality, and the plurality of openings may be apart from each other in the first horizontal direction (the X direction) and the second horizontal direction (the Y direction).

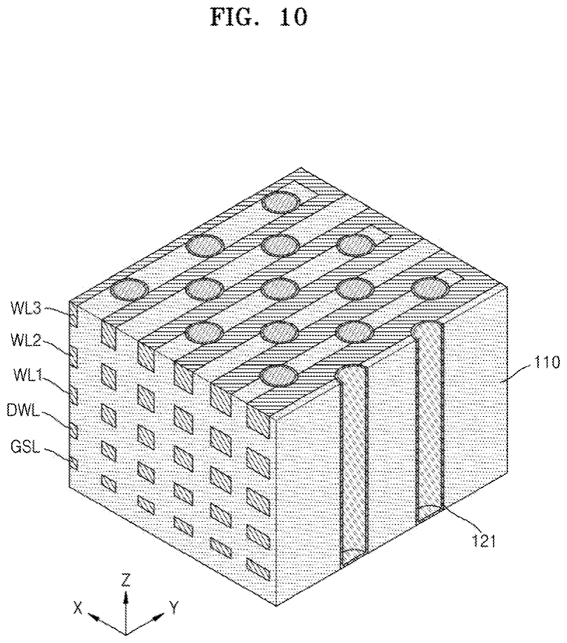

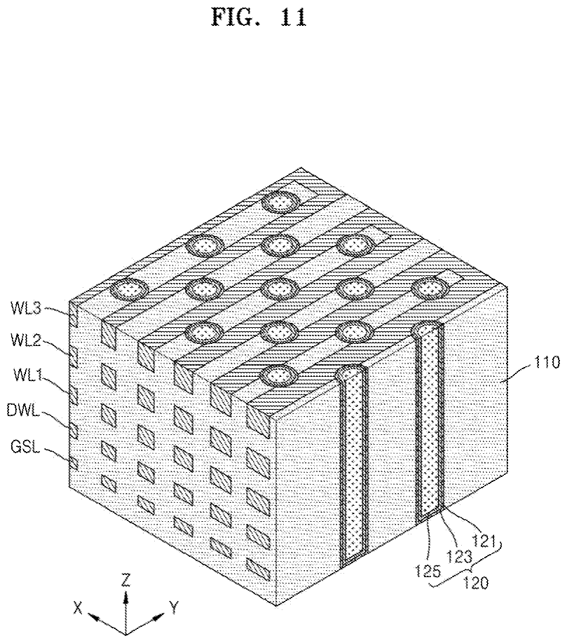

Referring to FIGS. 10 and 11, the channel structures 120 may be formed by sequentially forming the gate dielectric layer 121, the channel region 123, and the filling insulating layer 125 in each of the openings. The gate dielectric layer 121 may be conformally formed on the inner wall of the opening.

Referring back to FIGS. 1 and 2, the bit lines BL1, BL2, BL3, BL4, and BL5 may be formed on top of the plurality of memory cells formed as described above, thereby completing the manufacture of the memory device 10.

By way of summation and review, due to a reduction in size of memory cells for high integration, operating circuits or wiring structures included in memory devices for operation and electrical connection of the memory devices may be complicated. Accordingly, memory devices may have excellent electrical characteristics and data reliability, while having improved degree of integration.

One or more embodiments may provide a semiconductor memory device capable of high performance and high integration and improved stability.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor memory device, comprising:
a semiconductor substrate;
a plurality of word line layers on the semiconductor substrate, each word line layer of the plurality of word line layers including an insulating line and a word line;
a plurality of insulating layers in spaces between the plurality of word line layers, the plurality of insulating layers being apart from each other in a vertical direction on the semiconductor substrate;
a channel structure extending in the vertical direction on the semiconductor substrate, the channel structure including a channel region and a gate dielectric layer surrounding the channel region; and
a bit line on the channel structure, the bit line extending in a first horizontal direction perpendicular to the vertical direction and being connected to the channel structure,
wherein the word line of each word line layer of the plurality of word line layers has a meandering shape.

2. The semiconductor memory device as claimed in claim 1, wherein:
the plurality of word line layers include:
a first word line layer having a first thickness in the vertical direction;
a second word line layer having a second thickness in the vertical direction, the second word line layer being spaced apart from the first word line layer in the vertical direction and being on the first word line layer; and
a third word line layer having a third thickness in the vertical direction, the third word line layer being spaced apart from the second word line layer in the vertical direction and being on the second word line layer,
the first thickness of the first word line layer is less than the second thickness of the second word line layer, and
the second thickness of the second word line layer is less than the third thickness of the third word line layer.

3. The semiconductor memory device as claimed in claim 1, wherein the word line of each word line layer of the plurality of word line layers includes a plurality of edge lines and a plurality of horizontal lines, the plurality of edge lines extending in the first horizontal direction, and the plurality of horizontal lines extending in a second horizontal direction perpendicular to the vertical direction and the first horizontal direction.

4. The semiconductor memory device as claimed in claim 3, wherein each edge line of the plurality of edge lines is connected to at least two horizontal lines of the plurality of horizontal lines.

5. The semiconductor memory device as claimed in claim 3, wherein:
each edge line of the plurality of edge lines has a same width in the second horizontal direction, and
each horizontal line of the plurality of horizontal lines has a different width in the first horizontal direction from every other horizontal line of the plurality of horizontal lines.

6. The semiconductor memory device as claimed in claim 3, wherein each edge line of the plurality of edge lines does not vertically overlap the bit line.

7. The semiconductor memory device as claimed in claim 3, wherein:
one horizontal line of the plurality of horizontal lines is connected to a contact connected to a source line on at a first end of the one horizontal line that is opposite to a second end of the one horizontal line that is connected to the edge line,
each horizontal line of the plurality of horizontal lines has a same length in the second horizontal direction, and
widths of the plurality of horizontal lines in the first horizontal direction increase with increasing distance away from the contact in the first horizontal direction.

8. The semiconductor memory device as claimed in claim 7, wherein each insulating line is in a space between two horizontal lines of the plurality of horizontal lines and extends in the second horizontal direction.

9. The semiconductor memory device as claimed in claim 3, wherein each edge line of the plurality of edge lines is adjacent to sidewalls of the plurality of word line layers.

10. The semiconductor memory device as claimed in claim 1, wherein the channel structure passes through the plurality of word line layers and the plurality of insulating layers.

11. The semiconductor memory device as claimed in claim 1, wherein the plurality of insulating layers have the same thicknesses in the vertical direction.

12. A semiconductor memory device, comprising:
a semiconductor substrate;
a plurality of word line layers on the semiconductor substrate, each word line layer of the plurality of word line layers including an insulating line and a word line;
a plurality of insulating layers in spaces between the plurality of word line layers, the plurality of insulating layers being spaced apart from each other in a vertical direction on the semiconductor substrate;
a channel structure having a cylindrical shape and extending in the vertical direction on the semiconductor substrate, the channel structure including a channel region and a gate dielectric layer surrounding the channel region; and
a bit line on the channel structure, the bit line extending in a first horizontal direction perpendicular to the vertical direction and being connected to the channel structure,
wherein:
the word line of each word line layer of the plurality of word line layers has a meandering shape, and
thicknesses of the plurality of word line layers in the vertical direction increase with increasing distance away from the semiconductor substrate in the vertical direction.

13. The semiconductor memory device as claimed in claim 12, wherein:
the plurality of word line layers include:
a first word line layer having a first thickness in the vertical direction;
a second word line layer having a second thickness in the vertical direction, the second word line layer being spaced apart from the first word line layer in the vertical direction and being on the first word line layer; and
a third word line layer having a third thickness in the vertical direction, the third word line layer being spaced apart from the second word line layer in the vertical direction and being on the second word line layer,
the first thickness of the first word line layer is less than the second thickness of the second word line layer, and
the second thickness of the second word line layer is less than the third thickness of the third word line layer.

14. The semiconductor memory device as claimed in claim 12, wherein:
the word line of each word line layer of the plurality of word line layers includes a plurality of edge lines and a plurality of horizontal lines,
the plurality of edge lines extend in the first horizontal direction,
the plurality of horizontal lines extend in a second horizontal direction perpendicular to the vertical direction and the first horizontal direction, and
each insulating line is in a space between two horizontal lines of the plurality of horizontal lines and extends in the second horizontal direction.

15. The semiconductor memory device as claimed in claim 14, wherein:
the plurality of horizontal lines include a first horizontal line, a second horizontal line, a third horizontal line, and a fourth horizontal line spaced apart from each other in the first horizontal direction,
the insulating line includes a first insulating line between the first horizontal line and the second horizontal line, a second insulating line between the second horizontal line and the third horizontal line, and a third insulating line between the third horizontal line and the fourth horizontal line,
the first horizontal line, the second horizontal line, the third horizontal line, and the fourth horizontal line have a same length in the second horizontal direction, and
each of the first insulating line, the second insulating line, and the third insulating line extends with a constant width in the second horizontal direction.

16. The semiconductor memory device as claimed in claim 15, wherein:
the first horizontal line, the second horizontal line, the third horizontal line, and the fourth horizontal line have different widths from one another in the first horizontal direction, and
the first insulating line, the second insulating line, and the third insulating line have different widths from one another in the first horizontal direction.

17. The semiconductor memory device as claimed in claim 15, wherein a sum of a width of the second horizontal line in the first horizontal direction and a width of the first insulating line in the first horizontal direction is equal to a sum of a width of the third horizontal line in the first horizontal direction and a width of the second insulating line in the first horizontal direction.

18. A semiconductor memory device, comprising:
a semiconductor substrate;
a plurality of word line layers on the semiconductor substrate, each word line layer of the plurality of word line layers including an insulating line and a word line;
a plurality of insulating layers in spaces between the plurality of word line layers, the plurality of insulating layers being spaced apart from each other in a vertical direction on the semiconductor substrate;
a channel structure having a cylindrical shape and extending in the vertical direction on the semiconductor substrate, the channel structure including a channel region and a gate dielectric layer surrounding the channel region; and
a bit line on the channel structure, the bit line extending in a first horizontal direction perpendicular to the vertical direction and being connected to the channel structure,
wherein:
the word line of each word line layer of the plurality of word line layers has a meandering shape,
thicknesses of the plurality of word line layers in the vertical direction increase with increasing distance away from the semiconductor substrate in the vertical direction,
the plurality of word line layers include:
a first word line layer having a first thickness in the vertical direction;
a second word line layer having a second thickness in the vertical direction, the second word line layer being spaced apart from the first word line layer in the vertical direction and being on the first word line layer; and
a third word line layer having a third thickness in the vertical direction, the third word line layer being spaced apart from the second word line layer in the vertical direction and being on the second word line layer,
the first word line layer, the second word line layer, and the third word line layer are sequentially stacked on the semiconductor substrate,
the first thickness of the first word line layer is less than the second thickness of the second word line layer, and
the second thickness of the second word line layer is less than the third thickness of the third word line layer.

19. The semiconductor memory device as claimed in claim 18, wherein:
the word line of each word line layer of the plurality of word line layers includes a plurality of edge lines and a plurality of horizontal lines,
the plurality of edge lines extend in the first horizontal direction,
the plurality of horizontal lines extend in a second horizontal direction perpendicular to the vertical direction and the first horizontal direction,
one horizontal line of the plurality of horizontal lines is connected to a contact connected to a source line on at a first end of the one horizontal line that is opposite to a second end of the one horizontal line that is connected to the edge line,
each horizontal line of the plurality of horizontal lines has a different width in the first horizontal direction from every other horizontal line of the plurality of horizontal lines, and
widths of the plurality of horizontal lines in the first horizontal direction increase with increasing distance away from the contact in the first horizontal direction.

20. The semiconductor memory device as claimed in claim 19, wherein:
each insulating line includes a plurality of insulating patterns spaced apart from each other with a horizontal line of the plurality of horizontal lines therebetween, and
widths of the plurality of insulating patterns in the first horizontal direction decrease with increasing distance away from the contact in the first horizontal direction.
